(19) United States
(12) Patent Application Publication
(10) Pub. No.: US 2007/0121718 A1
(43) Pub. Date: May 31, 2007

(54) System and Method for Time-Domain Equalization in Discrete Multi-tone Systems

(76) Inventors: Chin-Liang WANG, Hsinchu (TW); Yuan-Shuo Chang, Hsinchu (TW)

Correspondence Address: SINORICA, LLC, 528 FALLSGROVE DRIVE, ROCKVILLE, MD, 20850, US

(21) Appl. No.: 11/668,012

(22) Filed: Jan. 29, 2007

Related U.S. Application Data
(63) Continuation-in-part of application No. 10/162,914, filed on Jun. 6, 2002.

(51) Int. Cl. H03H 7/30; H04L 5/12; H04B 1/10

(52) U.S. Cl. 375/233; 375/261; 375/350

(57) ABSTRACT

A novel time-domain equalizer (TEQ) is provided for the receiver of a Discrete Multi-tone (DMT) system to shorten the length of the effective channel impulse response. The TEQ is based on a variant of the conventional decision-feedback equalizer (DFE) structure along with a training method for the TEQ settings. By using this DFE-based TEQ for DMT systems, the data symbols transmitted through the effective shortened channel would be more reliable.

The prsent invention is a continuation-in-part of U.S. application Ser. No. 10/162,914, filed on Jun. 6, 2002, and is herein incorporated in its entirety by reference for all purposes.

### BACKGROUND OF THE INVENTION

1. Field of Invention

The present invention relates generally to a Discrete Multi-tone (DMT) system that transmits data over digital subscriber lines, more particularly, to a Time-Domain Equalizer (TEQ) of a DMT system receiver.

2. Description of Prior Art

Owing to the widespread popularity of World Wide Web, Internet access market emerges and grows at an amazingly fast pace. Before the eventual full deployment of fiber for broadband access, telecommunications operators need to seek for alternative solutions to provide low-cost high-speed access networks. Thanks to the ubiquity of copper telephone lines, Asymmetric Digital Subscriber Line (ADSL) technology serves as an interim technology that can transform the legacy of twisted pair telephone lines to a high-speed data network.

ADSL systems use the Discrete Multi-tone (DMT) modulation as the underlying transmission technology. FIG. 1 is a block diagram showing the structure of a DMT system receiving apparatus.

The interface circuit 110 includes the circuits for separating DMT signals from the existing POTS signals, as well as other well-known circuitry components for interfacing to copper twisted-pair telephone lines. The analog signals at the output of interface circuit 110 are converted into digital samples by an analog-to-digital converter (ADC) 120. These samples are then processed by a Time-Domain Equalizer (TEQ) 130 to avoid intersymbol interference between adjacent DMT symbols. The samples at the output of TEQ 130 are further partitioned into a parallel form by a Serial/Parallel converter (S/P) 140, wherein the boundary between successive DMT symbols is identified and a cyclic prefix is removed. It is noted that a cyclic prefix is a repetition of the last v samples of a DMT symbol and is appended to the beginning of the symbol where v is the predefined cyclic prefix length. A fast Fourier transform (FFT) circuit 145 then demodulates the partitioned digital samples into frequency domain values. These demodulated values are then passed through a frequency domain equalizer (FEQ) 150 and decoded by a Decoder 160 to recover the transmitted serial data stream.

For many multi-carrier transmission systems, a redundant sequence is inserted between adjacent data symbols to overcome the intersymbol interference (ISI) problem. In an ADSL transmission environment, a DMT symbol transmitted through the copper twisted-pair lines would be spanned extensively beyond its pre-defined interval to contaminate the next DMT symbols. Therefore, a lengthy overhead sequence, named cyclic prefix (CP) in ADSL systems, is appended to the beginning of each DMT symbol, and this results in a significant data rate loss. In order to achieve reasonable efficiency, a TEQ 130 is used to shorten the overall channel response within a predefined length. With a TEQ 130 employed in DMT systems, only fewer CP samples are required to be inserted between adjacent DMT symbols, thereby improving the data rate loss.

During an initialization procedure between two DMT transceivers, a training process is performed, by transmitting training data x(t) known at the two transceivers through a channel 105 to obtain the parameters for related functional blocks.

In the prior art proposals for deriving the TEQ settings during the initialization procedure, an additional finite impulse response (FIR) filter called the target impulse response (TIR) filter is employed to represent the effective shortened channel impulse response. The main idea of this design method is based on minimizing the difference between the outputs of the TEQ and TIR filters in the mean-squared error (MSE) sense. Among these MMSE (minimized mean-squared error) TEQ approaches, an efficient training method was described in “Equalizer training algorithms for multicarrier modulation systems” by J. S. Chow et al., IEEE International Conference on Communications, pages 761-765, May 1993. Although this approach provides us an effective way to design the TEQ, the system performance may suffer significant degradation for some practical twisted-pair phone lines.

In this present invention, we employ a variant of the conventional decision-feedback equalizer (DFE) structure to realize the TEQ in DMT systems. The novel TEQ structure in our invention consists of a feedforward filter, a feedback filter, and a delay line formed by concatenating a couple of delay units (not only one delay unit). Conceptually, the feedforward filter is a mean-squared whitened matched filter (MS-WMF), which whitens the received noise and produces an overall effective channel impulse response such that the output consists of only causal components. Due to the partial equalization property of a TEQ, not all residual causal ISI components need to be completely removed as the conventional DFE does. The TEQ, however, suppresses the still existing undesired causal ISI components outside the target impulse response after the received data are processed by the feedforward filter. By feeding the output of the variant DFE through the delay line and back to the input of the feedback filter, the feedback filter could reconstruct the unwanted components of the residual causal ISI. After the reconstructed residual causal ISI is subtracted from the output of the feedforward filter, more ISI will be suppressed. In other words, with the delay line and the feedback filter for processing the output of the feedforward filter in the way described above, we can form a novel TEQ structure to alleviate the ISI problem and thus to enhance the overall transmission performance. To obtain good TEQ settings (i.e., coefficients) with low computational complexity, a training method is also proposed for the new TEQ structure.

### SUMMARY OF THE INVENTION

A principal object of the present invention is based on the DFE concept to provide a TEQ structure for use in the DMT system receiver, instead of the conventional finite impulse response (FIR) filter structure, so that the combined impulse response has a minimum length to avoid intersymbol interference between adjacent DMT symbols.

A further object of the present invention is to provide a training method for the DFE-based TEQ structure in the DMT system receiver by updating the coefficients in the frequency domain and enforcing them to have consecutive nonzero taps in the time domain.

In accordance with the objects of the present invention, a DFE-based TEQ in the DMT system has been designed. The TEQ can shorten the length of the effective channel impulse response to be less than that of the cyclic prefix. With this TEQ for a DMT-based ADSL system, the transmission performance can be improved.

### BRIEF DESCRIPTION OF THE DRAWINGS

The present invention will be described in detail with reference to the accompanying drawings, wherein

FIG. 1 is a diagram of prior art showing a basic DMT structure

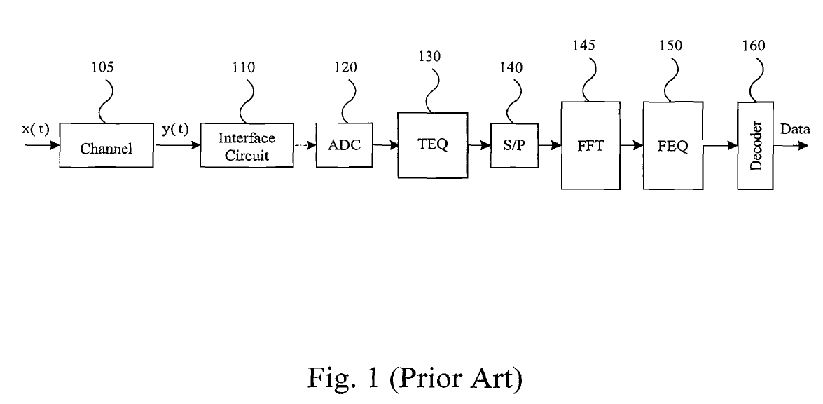

FIG. 2 is a diagram of the first preferred embodiment of the present invention;

FIG. 3 is a diagram of the second preferred embodiment of the present invention;

FIG. 4 is a diagram for explaining the training method of TEQ in the two preferred embodiments of the invention;

FIG. 5 is a flow chart form of a preferred TEQ training process of the present invention;

FIG. 6 is a diagram for explaining the updating step for the TIR filter in the present training method;

FIG. 7 is a flow chart for depicting the windowing operation on the TIR filter in the present training method;

FIG. 8 is a diagram for illustrating the updating step for the feedforward and feedback filters in the present training method; and

FIG. 9 is a flow chart for depicting the windowing operation on the feedforward and feedback filters in the present training method.

### DETAILED DESCRIPTION OF THE INVENTION

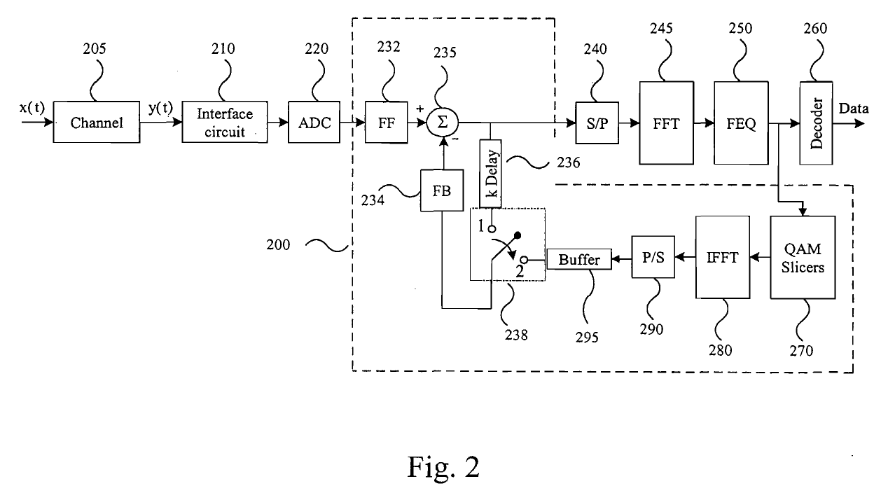

FIG. 2 illustrates a first preferred embodiment of the present invention. A time-domain equalizer (TEQ) system 200 comprises quadrature amplitude modulation (QAM) slicers 270 for mapping the outputs of the frequency domain equalizer (FEQ) 250 onto the QAM constellation for each subcarrier, an inverse fast Fourier Transformation device (IFFT) 280 for inverse fast Fourier transforming data generated by QAM slicers 270, a Parallel/Serial converter (P/S) 290 for converting the IFFT output data in parallel form into a serial form, a feedforward filter (FF) 232 for whitening the received noise and producing an overall effective channel impulse response such that the output only has causal components, a feedback filter (FB) 234 for reconstructing the undesired partial residual causal ISI, an adder 235 for subtracting the reconstructed partial ISI at the output of the feedback filter 234 from the output of the feedforward filter 232, a delay line 236 for delaying the samples at the adder 235 output to the input of the feedback filter 234, and a switch 238 for connecting the input end of feedback filter 234 to the first node 1 or the second node 2.

The timing for whichever being connected is described as follows.

First, assume that at time n, a complete DMT symbol corrupted with channel distortion and various noises is received and processed to recover its original symbol by the DMT receiver. Meantime, the rear k samples of the recovered DMT symbol are reconstructed and fed back along the path of the QAM slicers 270, the IFFT 280, and the P/S converter 290 to the Buffer 295 in time before the time n+1. Herein k is a parameter determined in the training procedure. Then, between the time n+1 and n+k, the first k digital samples of a new DMT symbol are received and processed by the feedforward filter 232 in sequence, and during this interval the input end of the feedback filter 234 should be switched to the second node 2 for feeding the k samples buffered at the time n back to the input of the feedback filter 234 to produce unwanted ISI. After the time n+k, the feedforward filter 232 continues processing the incoming digital samples at the ADC output, while the input end of the feedback filter 234 should be switched to the first node 1 for importing the samples from the output of the delay line 236 until a new complete DMT symbol is collected at the input of the FFT block. This delay line 236 is used to delay its input by k operating clock cycles making the feedback filter 234 can generate partial causal ISI outside the target impulse response. These undesired partial causal ISI are further subtracted at the output of feedforward filter 232 to alleviate ISI problem between received DMT symbols. Again, at the time n+v+N, the k rear samples of the current DMT symbol are reproduced at the second node 2 and the above operations will be followed repeatedly for the coming DMT symbols. Herein, v is the length of cyclic prefix and N is the FFT size. Unlike the conventional DFE using one-cycle delayed decisions as the input of its feedback filter to reconstruct all residual causal ISI components, the proposed DFE-based TEQ employs a programmable delay line, instead of one delay unit, that makes the feedback filter more flexible to produce undesired partial ISI outside the target impulse response. Moreover, under the assumption that the TEQ settings are well obtained by the present training method during the initialization procedure, the feedback filter 234 could use the delayed signals without decisions as its input when the switch is connected to the first node 1. However, this TEQ structure requires large computation resources, an alternative structure for TEQ is proposed as our second preferred embodiment of the present invention.

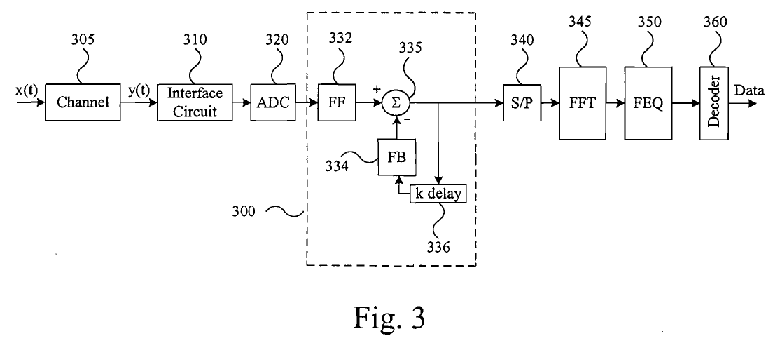

FIG. 3 illustrates a second preferred embodiment of the present invention. A time-domain equalizer (TEQ) 300 comprises a feedforward filter (FF) 332 for whitening the received noises and producing an overall effective channel response such that the output only has causal components, a feedback filter (FB) 334 for reconstructing the partial residual causal ISI, and a delay line 336 for delaying the samples at the adder 335 output to the input of the feedback filter 334. The delay line 336 consisting of programmable delay units can delay the output samples of the adder 335 for more than one clock cycle to the feedback filter 334 such that the feedback filter 334 can produce partial residual causal ISI for partial ISI suppression at the feedforward filter 332 output.

In the second preferred embodiment of the present invention, the time-domain equalizer (TEQ) 300 reduces the computational complexity of the time-domain equalizer (TEQ) 200 of the first preferred embodiment of the present invention dramatically at the cost of slight performance degradation.

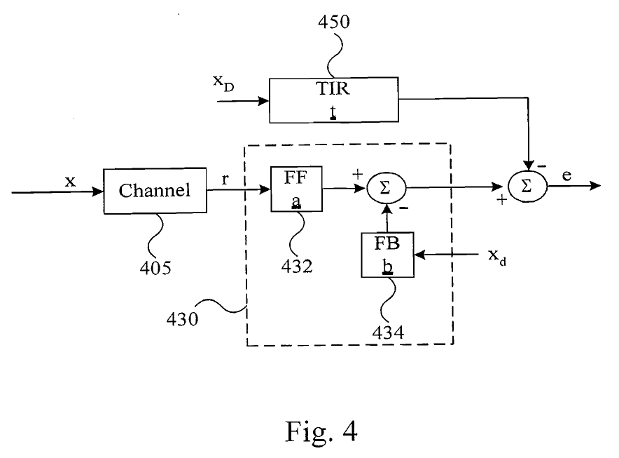

A diagram for explaining the training method for the TEQ in the two preferred embodiments (the time-domain equalizer (TEQ) 200 and 300) of the present invention is shown in FIG. 4. x denotes the training data, Nₐ denotes the number of taps in the feedforward filter (FF) 432, N_{b} denotes the number of taps in the feedback filter (FB) 434, and Nₜ denotes the number of taps in the target impulse response (TIR) filter 450. Then, we define the vectors a=[a(0), a(1), . . . , a(Nₐ−1)], b=[b(0), b(1), . . . , b(N_{b}−1)], and t=[t(0), t(1), . . . , t(Nₜ−1)], where a, b, and t represent the taps of the FF 432, FB 434, and TIR filters 450, respectively.

The training data consisting of a sufficient number of identical DMT symbols are passed through a twisted-pair telephone line channel 405. Due to the periodic nature of the training data, the received data are also periodic and can be obtained by cyclically convoluting x with the impulse response h of the channel 405. (This property implies the equivalent multiplication of x and h in frequency domain) The received data, r, are used as the input data for the feedforward filter (FF) 432. The input data x_{d} to the feedback filter (FB) 434 is the training data x delayed by d samples, where d is determined in training procedure. One additional filter called Target Impulse Response (TIR) filter 450 is employed to speed up the convergence of the TEQ filter 430. The input data x_{D} for the TIR filter 450 is the training data x delayed by D samples, where D represents the physical channel delay.

The filter coefficients of the feedforward filter 432 and the feedback filter 434 are adjusted to minimize the mean-square error between the outputs of the TEQ filter 430 and the TIR filter 450.

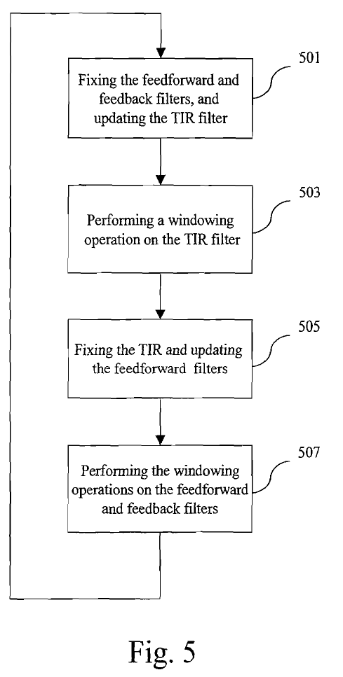

FIG. 5 is a flow chart form of a preferred TEQ training process of the present invention. The training process comprises the steps:
501: fixing the feedforward and feedback filters and then updating the TIR filter in the frequency domain by the FLMS (frequency-domain least mean-square) method;
503: performing a windowing operation on the TIR filter in the time domain to limit the taps outside the window of length v+1 to be zeros;
505: fixing the TIR filter and then updating the feedforward and feedback filters in the frequency domain by the FLMS (frequency-domain least mean-square) method; and
507: performing the windowing operations on the feedforward and feedback filters in the time domain to limit them to have only Nₐ and N_{b} consecutive non-zero taps respectively, then returning to the step 501.

The above steps are repeated until the training period expires.

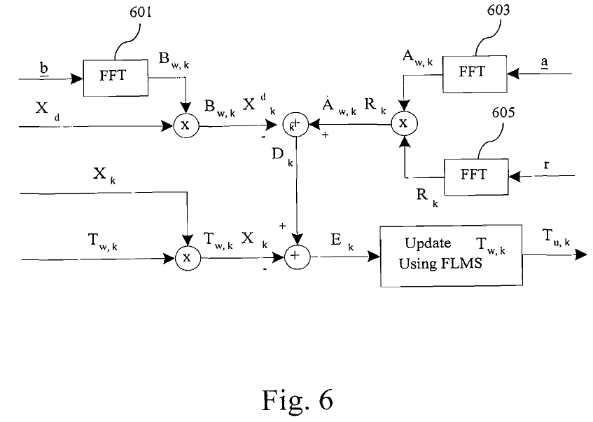

A diagram for explaining the updating step 501 for the TIR filter in the present training method is shown in FIG. 6. Since the updating operation 501 for the TIR filter is performed in the frequency domain, the coefficients of the feedforward, feedback and TIR filters should be transformed into the corresponding frequency domain coefficients first. Accordingly, the length of the column vectors a, b, and t should be extended to the FFT size by appending sufficient zeros behind them. Then the extended taps of the feedforward, feedback and TIR filters are converted by the FFT operation to obtain the corresponding frequency domain taps A_{w,k}, B_{w,k}, and T_{w,k}, where the lower script w represents the filter that has been windowed and k represents the subcarrier index. Similarly, the input data x_{D} to the TIR filter, the input data x_{d} to the feedback filter and the received data r are transformed into the complex-valued samples of Xₖ, X^{d}ₖ and Rₖ as well. Then the complex-valued output samples of the feedforward, feedback, and TIR filters could be generated by multiplying A_{w,k} with Rₖ, B_{w,k} with X^{d}ₖ and T_{w,k} with Xₖ, respectively. To derive the desired signals, Dₖ, the output samples of the feedback filter are subtracted from the output samples of the feedback filter in the frequency domain, which is shown in the following equation [1]:
Dₖ=A_{w,k}Rₖ−B_{w,k}X^{d}ₖ [1]

Further the error signals, Eₖ, would be obtained as the following equation [2]:
Eₖ=Dₖ−T_{w,k}Xₖ [2]

Eventually, the taps of TIR filter in the frequency domain are updated by the following equation [3];
T_{u,k}=T_{w,k}+αEₖ(Xₖ)* [3]
where the lower script u represents that the TIR filter remains unwindowed, α is the step size in the FLMS algorithm, and (Xₖ)* is the complex-conjugate value of Xₖ.

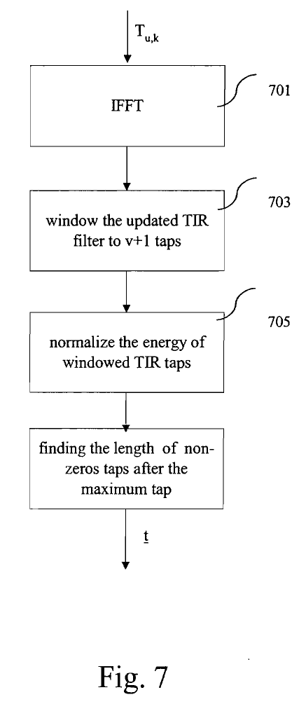

FIG. 7 is a flow chart for depicting the windowing operation 503 on the TIR filter. Because the windowing operation is performed in the time domain, the frequency domain taps of the updated TIR filter, T_{u,k}, should be transformed into the corresponding time-domain taps. Then the time-domain taps of the TIR filters should be limited to v+1 consecutive non-zero taps by placing a fixed window function on it. The starting position of the window of length v+1 is aligned with the tap of TIR filter that corresponds to the physical channel delay and then the taps outside the window would be discarded to acquire the TIR filter t of length v+1. Finally, in order to prevent the windowed taps of the TIR filter from converging to the trivial solution, i.e. all taps of t are zeros; the energy of t should be normalized to some preset value.

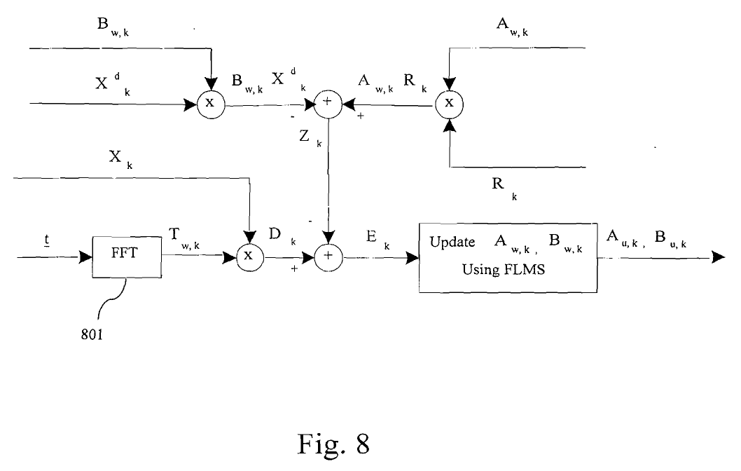

FIG. 8 illustrates the updating step 505 for the feedforward and feedback filters. Similar to the updating step 501, the taps of the feedforward, feedback, and TIR filters are transformed by the FFT operation to derive their corresponding frequency domain taps A_{w,k}, B_{w,k} and T_{w,k}. The input data x_{D} to the TIR filter, the input data x_{d} to the feedback filter, and the received data r are also transformed into these complex-valued data Xₖ, X^{d}ₖ and Rₖ, respectively. Afterward the frequency domain samples at the output of the feedforward, feedback, and TIR filters could be generated by multiplying A_{w,k} with Rₖ, B_{w,k} with X^{d}ₖ and T_{w,k} with Xₖ, respectively. At this time the complex-valued samples at the TIR filter output are used as the desired signals that are calculated according to the following equation [4].
Dₖ=T_{w,k}Xₖ [4]
Let Zₖ denote the difference between the output samples of the feedforward filter and the feedback filter in the frequency domain. It can be expressed as the following equation [5]:
Zₖ=A_{w,k}Rₖ−B_{w,k}Xₖ [5]
Then the error signals, Eₖ, would be obtained according to the equation [6].
Eₖ=Dₖ−Zₖ [6]

Finally the taps of the feedforward and feedback filters in the frequency domain are updated by the equations [7] and [8], respectively.
A_{u,k}=A_{w,k}+βEₖR*ₖ [7]
B_{u,k}=B_{w,k}+γEₖ(X^{d}ₖ)* [8]
Herein the parameters of β and γ are the step sizes for updating the feedforward and feedback filters in the FLMS algorithm. R*ₖ and (X^{d}ₖ)* are the complex-conjugate values of Rₖ and X^{d}ₖ.

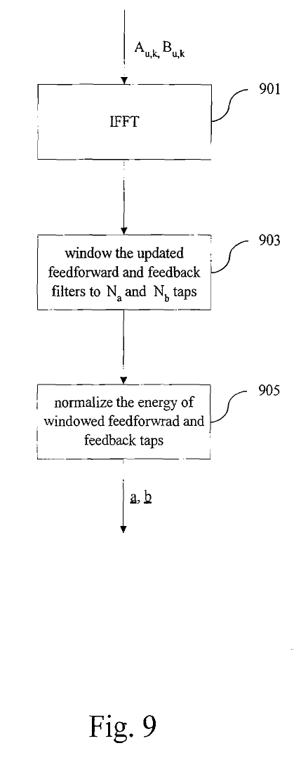

FIG. 9 is a flow chart for depicting the windowing operation 507 on the feedforward and feedback filters. First, the updated frequency domain taps of the feedforward and feedback filters are transformed via the IFFT operation into the time-domain taps. Then we perform the windowing operation on the feedforward and feedback filters to limit them to have Nₐ and N_{b} non-zero consecutive taps. The windowing process would be performed circularly to find Nₐ consecutive taps for the feedforward filter (N_{b} consecutive taps for the feedback filter), which has maximum energy inside this window. Finally, in order to prevent the windowed taps of the feedforward and feedback filters from converging to the trivial solutions, i.e. all taps of a and b are zeros, the energy of a and b should be normalized to some preset value.

While the invention has been particularly shown and described with reference to the preferred embodiments thereof, it will be understood by those skilled in the art that many alternations and modifications may be made without departing from the spirit scope of the invention.

What is claimed is:

1. A time-domain equalizer system, comprising:
Quadrature amplitude modulation (QAM) slicers map outputs of frequency-domain equalizer (FEQ) to a set of pre-defined points on the QAM constellation for each subscriber, wherein
the QAM slicers receive the outputs of the FEQ by connecting to the FEQ;
an inverse fast Fourier transformation unit (IFFT) connects to the QAM slicers for inverse fast Fourier transforming recovered complex-valued frequency-domain symbols by the QAM slicers into real-valued time-domain symbols;
a parallel to serial converter (P/S) receives the output of the IFFT and converts said parallel transformed data into serial data;
a feedforward filter (FF) equalizes pre-cursor intersymbol interference (ISI) and whitens input noise contained in input signals;
a feedback filter (FB) produces partial residual post-cursor ISI for removing undesired ISI outside the target impulse response;
an adder having a first input for receiving output of the feedforward filter, and a second input for receiving output of the feedback filter for subtracting an output of the feedback filter from an output of the feedforward filter to shorten an overall effective channel, wherein
the adder output connects to the serial to parallel converter (S/P);
a delayed-line unit connects to the adder for delaying the signals at the adder output to a switch for a number of clock cycles where the number of clock cycles is determined in a procedure of windowing a target impulse response filter during a training mode; and
a switch for selectively connecting an output of said delayed-line unit to an input of the feedback filter.

2. The time-domain equalizer system according to claim 1, wherein said switch further connects said input of said feedback filter to a buffered output of the parallel/serial converter.

3. The time-domain equalizer system according to claim 1, wherein said feedforward filter connects to an analog-to-digital converter (ADC) and continues processing incoming signal samples from the ADC and the output of the delayed-line unit is connected to said input of said feedback filter for feeding delayed signals at said output of said delay-line unit back to said feedback filter during a predetermined timing period.

4. The time-domain equalizer system according to claim 1, wherein said input of said feedback filter is switched to said buffered output of the parallel/serial converter for feeding recovered signals from said QAM slicers back to the input of said feedback filter during a predetermined timing period.

5. A time-domain equalizer system comprises:
a feedforward filter (FF) equalizes pre-cursor intersymbol interference (ISI) and whitens input noise contained in input signals;
a feedback filter (FB) produces partial residual post-cursor ISI for undesired ISI suppression;
an adder connects to the feedforward filter and the feedback filter for subtracting an output of the feedback filter from an output of the feedforward filter to shorten an overall effective channel impulse response; and
a delayed-line unit connects to the adder and delays signals at the adder output by implementing predetermined clock cycles wherein the delayed signals are input to the feedback filter, and the predetermined clock cycles is determined in a procedure of windowing a target impulse response filter during a training mode.

6. The time-domain equalizer system of claim 5 comprises,
an adder having a first input for receiving output of the feedforward filter, and a second input for receiving output of the feedback filter for subtracting an output of the feedback filter from an output of the feedforward filter to shorten an overall effective channel, wherein
the adder output connects to the serial to parallel converter (S/P) and the delay-line unit.
